(19) United States
(12) Patent Application Publication
(10) Pub. No.: US 2009/0040573 A1
(43) Pub. Date: Feb. 12, 2009

(54) IMAGE PROCESSING APPARATUS AND IMAGE PROCESSING METHOD

(75) Inventor: Hak-ju LEE, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 12/176,505

(22) Filed: Jul. 21, 2008

(30) Foreign Application Priority Data
Aug. 7, 2007 (KR) 2007-79144

(51) Int. Cl. H04N 1/46; G03F 3/08

(52) U.S. Cl. 358/505; 358/518

(57) ABSTRACT

An image processing apparatus and an image processing method, the image processing apparatus including: an image processor to convert a first scan image having a first color gamut, into a second scan image having a second color gamut, and to generates an image file according to the second scan image having a profile including information on a difference between the first and second color gamuts; and a controller to determine the difference between the first and second color gamuts, and to control the image processor to generate the image file.

### CROSS-REFERENCE TO RELATED APPLICATION

This application claims the benefit of Korean Application No. 2007-79144, filed Aug. 7, 2007, in the Korean Intellectual Property Office, the disclosure of which is incorporated herein by reference.

### BACKGROUND OF THE INVENTION

1. Field of the Invention

Aspects of the present invention relate to an image processing apparatus and an image processing method, and more particularly, to an image processing apparatus and an image processing method, which can convert a scan image into an image having a predetermined color gamut.

2. Description of the Related Art

An image processing apparatus, such as a computer system, functions as a host device of a scanner and/or a multi-function device (hereinafter a scanning device). The image processing apparatus controls an operation of the scanning device, according to a user's commands.

More specifically, the image processing apparatus scans an object having a picture and/or text, etc., to generate an image (hereinafter a scan image), processes the scan image, and outputs an image file through a monitor.

Color input and output devices, such as, a monitor, a scanner, a camera, and a printer, which realize colors, may have different ranges of realizable colors, i.e., different color gamuts. If the same image is realized by various input and output devices, the image may be differently realized, due to color gamut differences between the output devices. The range of color realization of an input and output device is determined by primary colors of the device.

As shown in FIG. 1, the range of color realization of the input and output device is determined by connecting the primary colors of the color realization device in a color space. If the color realization device uses primary colors P1, P2, and P3, a triangular internal domain of a first color gamut (GAMUT 1) encompasses the range of color realization (color band) of the color realization device. Likewise, if the color realization device uses primary colors P1′, P2′, and P3′, a second color gamut (GAMUT 2) encompasses the range of color realization thereof.

If an input image and the device reproducing the input image, have different color gamuts, color gamut mapping is used to properly convert the color gamut of the input image, to improve color realization performance. For example, referring to FIG. 1, if the first color gamut of a scan image is larger than the second color gamut of a monitor of the image processing apparatus, the image processing apparatus compresses the first color gamut of the scan image to be within the second color gamut of the monitor, thereby producing a color-compressed image. However, part of the color gamut (clipped part), which is outside of the color gamut, may be clipped while being compressed.

If the color-compressed image is realized through, of an application program having a larger third color gamut (GAMUT 3), the color gamut of the color-compressed image may be extended. However, the clipped part is not supplied during the color gamut extension, thereby failing to display the image correctly. Particularly, if the application program does not support a color management system (CMS), a compressed image having no color gamut mapping may not be correctly displayed on the monitor. Further, if the color-compressed image is printed by a printer, the color information of the clipped part is not supplied, thereby possibly altering the color of an output/printed image, with respect to the original scan image.

### SUMMARY OF THE INVENTION

Aspects of the present invention provide an image processing apparatus and an image processing method, which can prevent the color of an output image from being different from that of an original image, when a related image file is transferred between devices having different color gamuts.

Aspects of the present invention provide an image processing apparatus and an image processing method, which can display the color of an output image, like an original scan image, even if the color gamut of the scan image is compressed and then extended.

Aspects of the present invention provide an image processing method, including: scanning an image to generate a scan image having a first color gamut; converting the scan image, into a converted scan image having a second color gamut; determining a difference between the first color gamut and the second color gamut, with respect to the converted scan image; and generating an image file having a profile. The profile can include information on the determined difference between the color gamuts.

Aspects of the method may further include displaying the image file, based on the profile.

According to aspects of the present invention, the second color gamut may have a more narrow range of color realization than the first color gamut.

According to aspects of the present invention, the profile may further include information on a clipped part of the converted scan image.

According to aspects of the present invention, the second color gamut may include an sRGB color space.

According to aspects of the present invention, the method may further include storing the profile and the image file having the profile.

According to aspects of the present invention, the profile may further include reverse conversion information of the image file.

According to aspects of the present invention, the generating of the image file may include adding the reverse conversion information to the image file, in a certain pattern that is restorable by a printing device.

Aspects of the present invention relate to an image processing apparatus including: an image processor that converts a scan image having a first color gamut into a converted scan image having a second color gamut, and generates an image file; and a controller that determines a difference between the first color gamut and the second color gamut, with respect to the converted scan image, and controls the image processor, to generate an image file having a profile including information on the determined difference between the color gamuts.

According to aspects of the present invention, the apparatus may further include a display unit, which displays the image file, based on the profile.

According to aspects of the present invention, the second color gamut may have a more narrow range of color realization than the first color gamut.

According to aspects of the present invention, the profile may further include information on a clipped part of the converted scan image.

According to aspects of the present invention, the second color gamut may include an sRGB color space.

According to aspects of the present invention, the apparatus may further include a storage unit, which stores the image file having the profile.

According to aspects of the present invention, the profile may include reverse conversion information of the image file.

According to aspects of the present invention, the controller may add the reverse conversion information of the image file to the image file, in a certain pattern that is restorable by a printing device.

Additional aspects and/or advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the exemplary embodiments, taken in conjunction with the accompanying drawings, of which:

FIG. 1 illustrates exemplary color gamuts of color input and output devices;

FIGS. 2 and 3 are block diagrams of an image processing apparatus, according to an exemplary embodiment of the present invention;

FIG. 4 illustrates a profile that is generated, according to an exemplary embodiment of the present invention; and

FIG. 5 is a flowchart to describe a control method of the image processing apparatus, according to an exemplary embodiment of the present invention.

### DETAILED DESCRIPTION OF THE EXEMPLARY EMBODIMENTS

Reference will now be made in detail to the exemplary embodiments of the present invention, examples of which are illustrated in the accompanying drawings, wherein like reference numerals refer to the like elements throughout. The exemplary embodiments are described below, in order to explain the aspects of the present invention, by referring to the figures.

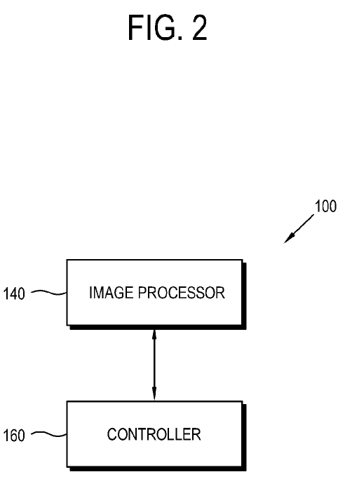

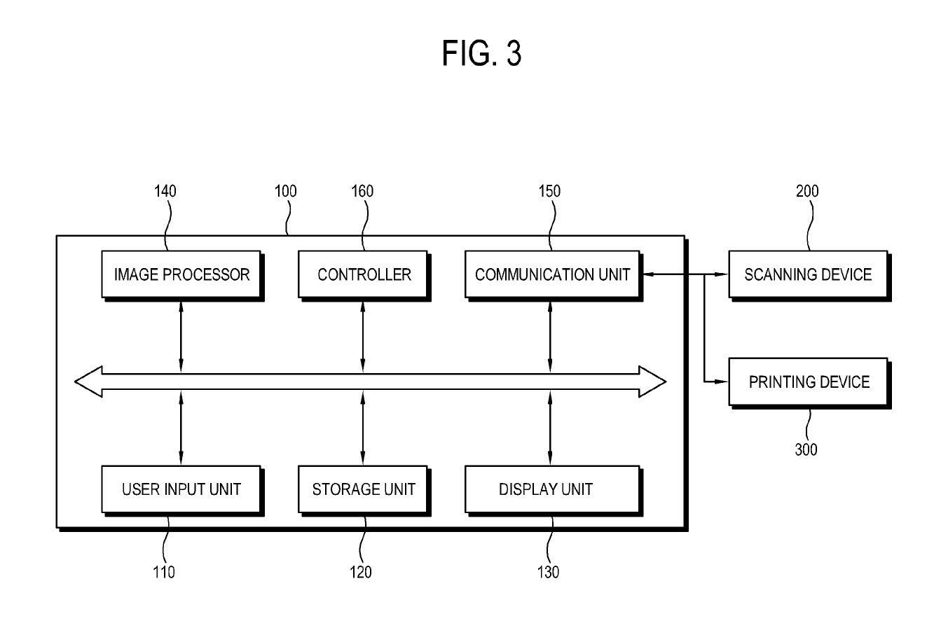

FIGS. 2 and 3 are block diagrams of an image processing apparatus 100, according to an exemplary embodiment of the present invention. The image processing apparatus 100 may include a computer system, which is a host device of a scanning device 200.

The image processing apparatus 100 (host device) controls an operation of the scanning device 200, according to a user's command. More specifically, the image processing apparatus 100 scans an object having a picture and/or text, etc., to generate a scan image (original scan image) having a first color gamut. The image processing apparatus 100 processes the scan image, to generate an output image (converted image) having a second color gamut. The first color gamut may include a range of color realization that includes an RGB color space of the scanning device 200.

As shown in FIGS. 2 and 3, the image processing apparatus 100 includes a user input unit 110, a storage unit 120, a display unit 130, an image processor 140, a communication unit 150, and a controller 160. The user input unit 110 receives a user's command to scan an image, and transmits the command to the controller 160. The user input unit 110 may be, for example, a keyboard, a touch screen, a mouse, etc.

The storage unit 120 stores various data, including information on the color gamut realized by the image processing apparatus 100, and image files generated by the operation thereof. The display unit 130 can be, for example, a cathode ray tube (CRT), a liquid crystal display (LCD), a plasma display, etc. The display unit 130 is capable of realizing colors that are included in the second color gamut. The second color gamut may include a range of color realization in an sRGB color space. The second color gamut may have an extended range of color realization, by using four or more primary colors.

The image processor 140 processes the original scan image, and generates an image file, according to the control of the controller 160. The communication unit 150 communicates with the scanning device 200, according to the control of the controller 160. The communication unit 150 may include a communication port to connect with the scanning device 200, or alternatively, may include a wired/wireless communication module.

The controller 160 controls the overall operations of the image processing apparatus 100. If a user inputs an image scan command, the controller 160 transmits the scan command to the scanning device 200. The controller 160 controls the image processor 140 to receive an original scan image generated by the scanning device 200, having the first color gamut, through the communication unit 150. The controller 160 controls the image processor 140 to generate the image file, by processing the original scan image.

The controller 160 performs gamut mapping, so that the original scan image can be displayed in different color gamut. For example, the scanning device 200 and the image processing apparatus 100 can have the different color gamuts, i.e., first color gamut and the second color gamut. More specifically, the controller 160 reads information on the second color gamut, from the image processing apparatus 100, and performs the gamut mapping, by converting the original scan image, having the first color gamut, into a converted scan image having the second color gamut.

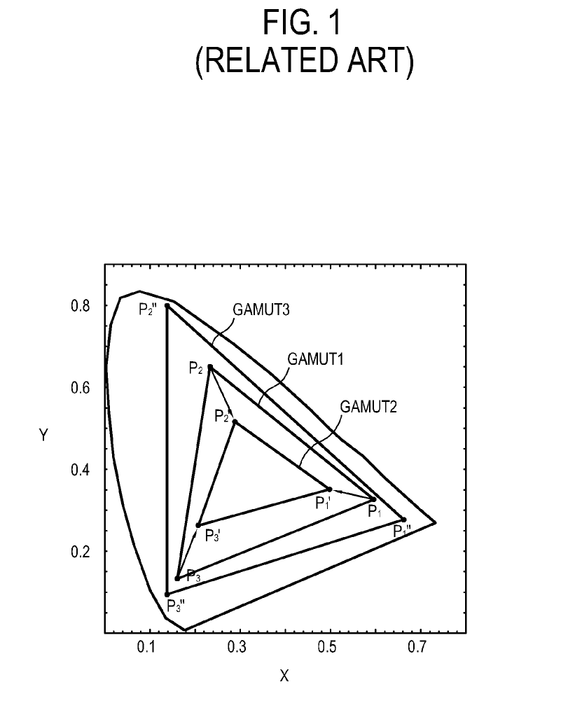

Returning to FIG. 1, if the range of color realization of the second color gamut (GAMUT 2) is smaller than the range of color realization of the first color gamut (GAMUT 1), the controller 160 may perform a gamut compression, to map a clipped part of the original scan image (colors of the original scan image that are disposed outside of the second color gamut) to be disposed inside of the second color gamut, thereby forming a converted scan image.

The clipped part may be clipped during the color gamut compression. The clipped part may not be properly expressed, if the converted scan image is displayed in an application program (to be described later) having a third color gamut (GAMUT 3). The controller 160 determines the difference between the ranges of color realization of the first color gamut and the second color gamut, with respect to the converted scan image, and generates a profile having information on the determined difference between the ranges of color realization (differences between the color gamuts). The generated profile includes information on the clipped part of the original scan image.

The controller 160 generates an image file that includes the converted scan image and the generated profile. The generated profile can be embedded in the converted scan image, and identified with a predetermined tag. If an image corresponding to the image file is displayed, by the application program having the third color gamut, which is larger than the second color gamut, the image processing apparatus 100 may display the converted scan image as a restored version of the original scan image, by using the profile embedded in the image file. The restored version can be a close approximation of the original scan image, or a substantially exact copy of the original scan image.

Conventionally, the converted scan image would be displayed in the application program (having the larger third color gamut), as having colors of the second color gamut. Contrarily, the image processing apparatus 100 may display all the colors of the original scan image, i.e., the colors of the original scan image realizable in the first color gamut, in the application program having the third color gamut, by using the profile. The profile has the information on the difference between the ranges of color realization, such as, information on the clipped part.

The third color gamut may include the range of color realization in a color space, such as, ADOBE RGB, Wide Gamut RGB, etc. The application program may not support a color management system (CMS). More specifically, the application program having the third color gamut, can provide a larger range of color realization, for example, the application program can include a graphics program, such as, PHOTOSHOP, or ILLUSTRATOR, to edit or revise the scan image.

The generated profile may further include reverse conversion information, to convert the converted image file back into the color gamut of the original scan image i.e., producing a restored version of the original scan image. If a printing device 300 is used to reverse-map the converted scan image, having the second color gamut, into the first color gamut of the original scan image, an image having the colors of the original scan image may be output. The printing device 300 may include an output device, such as, a printer, a multi-function device, or the like.

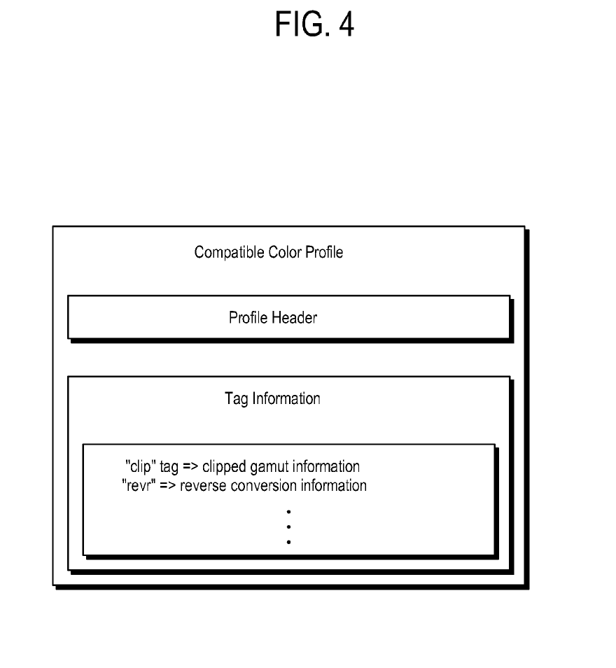

FIG. 4 illustrates an example of a profile generated, according to an exemplary embodiment of the present invention. As shown therein, the profile may include a predetermined tag, e.g., an sRGB_compatible.icc including a header and tag information. More specifically, the tag information includes information on the clipped part, the reverse conversion information, etc.

The controller 160 controls the image processor 140, to generate an image file having the profile. The profile includes the information on the difference between the first color gamut and the second color gamut. The generated image file is displayed on the display unit 130, according to the range of color realization of the second color gamut, based on the generated profile. The image file having the profile is stored in the storage unit 120.

In exemplary embodiments, the printing device 300 may not properly realize the colors of the original scan image, if the printing device 300 does not receive the profile, or if the printing device does not read the supplied profile. In such exemplary embodiments, the controller 160 may control the image processor 140 to add the clipped part information, and the reverse conversion information of the generated image file, to the image file, in a certain restorable pattern. For example, the image processing apparatus 100 may convert the original scan image having the first color gamut, into a converted scan image having a second color gamut, such as, sRGB, or ADOBE RGB, and add the clipped part information and the reverse conversion information to the image file, in a certain pattern. The image file is then output to the printing device 300.

The particular pattern may be restored such that a restored version of the original scan image can be displayed (printed) by the printing device 300, even though the restored version is not displayed on the image processing apparatus 100. The printing device 300 can include a module to restore the pattern included in the image file, and may output the original scan image, even if it does not receive the profile information. In other words, the profile information can be imbedded in the converted scan image of the image file.

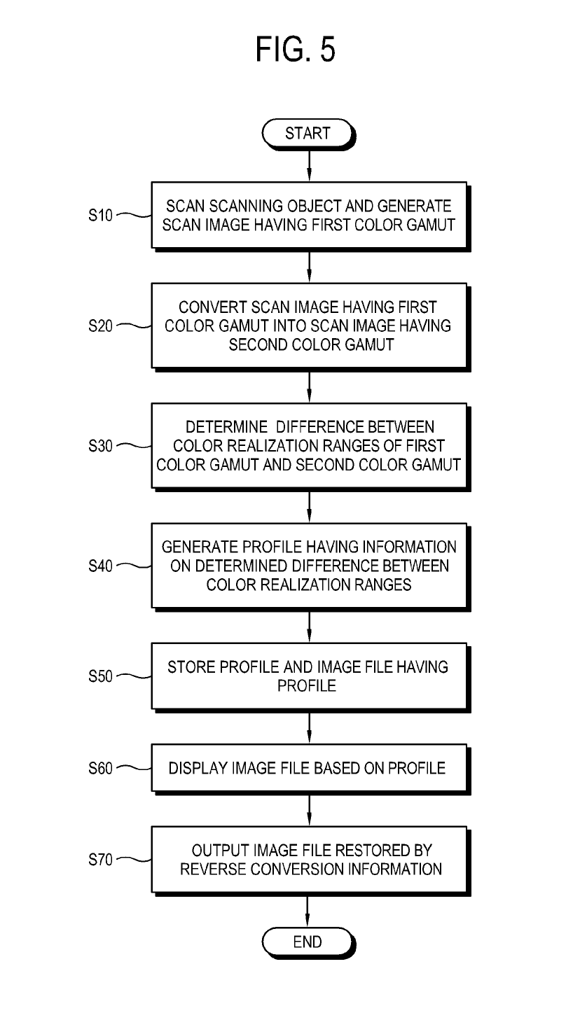

An image processing process, of the image processing apparatus 100 having the foregoing configuration, will be described with reference to FIG. 5. The scanning device 200 receives a scan command from a user, through the host device 100, or the scanning device 200 itself, which signals the scanning device to scan a scanning object, and transmits scan data produced by the scanning device 200, to the host device 100 (S10).

The controller 160 generates an original scan image having the first color gamut, from the received scan data. The controller 160 converts the original scan image into the second color gamut (S20), thereby forming a converted scan image. The controller 160 determines the difference between the first color gamut and the second color gamut, with respect to the converted scan image (S30).

The second color gamut may include the sRGB color space. The second color gamut may define a smaller color space than the first color gamut.

The controller 160 generates a profile that includes information on the difference between the first and second color gamuts determined at operation S30 (S40). The controller 160 embeds the generated profile in an image file. The profile may include information on a clipped part of the original scan image, and reverse conversion information of the image file. The controller 160 may store the generated profile and the image file in the storage unit 120 (S50).

The stored image file may be displayed as a restored version of the original scan image, including the clipped part, by using the profile, even in the application program has a larger color gamut. The stored image file may be printed with colors close to the original scan image, by the printing device 300, according to the reverse conversion information.

The controller 160 may add the clipped part information and the reverse conversion information of the generated image file, to the image file in a certain pattern, which is restorable by the printing device. The controller 160 displays the image file on the display unit 130, based on the profile (S60).

The controller 160 transmits the image file, which has the clipped part information and the reverse conversion information, to the printing device 300. The printing device 300 receives the image file, and outputs (prints) a restored version of the original image file, which is restored according to the reverse conversion information (S70).

As described above, aspects of the present invention provide an image processing apparatus and an image processing method, which can prevent color images from differing from original images, between devices having different color gamuts. Aspects of the present invention provide an image processing apparatus and an image processing method, which can display an original image, even if the color gamut thereof is compressed and then extended.

Although a few exemplary embodiments of the present invention have been shown and described, it will be appreciated by those skilled in the art that changes may be made in these exemplary embodiments, without departing from the principles and spirit of the invention, the scope of which is defined in the claims and their equivalents.

What is claimed is:

1. An image processing method, comprising:
generating an original scan image having a first color gamut;
converting the original scan image into a converted scan image having a second color gamut;
determining a color space difference between the first color gamut and the second color gamut, with respect to the converted scan image; and
generating an image file comprising the converted scan image and a profile comprising the determined color space difference.

2. The method according to claim 1, further comprising displaying the image file, according to the profile.

3. The method according to claim 1, wherein a color space of the second color gamut is smaller than a color space of the first color gamut.

4. The method according to claim 1, wherein the profile further comprises information on a clipped part of the original scan image, that is outside the second color gamut.

5. The method according to claim 1, wherein the second color gamut comprises an sRGB color space.

6. The method according to claim 1, further comprising storing the image file.

7. The method according to claim 1, wherein the profile further comprises reverse conversion information, to convert the convert scan image into a restored version of the original scan image.

8. The method according to claim 7, wherein the generating of the image file comprises adding the reverse conversion information to the image file, in a pattern that is restorable by a printing device.

9. An image processing apparatus, comprising:
an image processor to convert an original scan image having a first color gamut, into a converted scan image having a second color gamut, and to generate an image file comprising the converted scan image and a profile that comprises information on a color space difference between the first and second color gamuts; and
a controller to determine the color space difference, with respect to the converted scan image, and to control the image processor to generate the image file.

10. The apparatus according to claim 9, further comprising a display unit to display the image file, based on the profile.

11. The apparatus according to claim 9, wherein a color space of second color gamut is smaller than a color space of the first color gamut.

12. The apparatus according to claim 9, wherein the profile further comprises information on a clipped part of the original scan image, which is outside the second color gamut.

13. The apparatus according to claim 9, wherein the second color gamut comprises an sRGB color space.

14. The apparatus according to claim 9, further comprising a storage unit to store the image file.

15. The apparatus according to claim 9, wherein the profile further comprises reverse conversion information of the image file, to convert the convert scan image into a restored version of the original scan image.

16. The apparatus according to claim 15, wherein the controller adds the reverse conversion information to the image file, in a pattern that is restorable by a printing device in the first color gamut.

17. The apparatus according to claim 15, wherein the controller embeds the reverse conversion information in the converted scan image of the image file.

18. The method according to claim 7, wherein the generating of the image file comprises embedding the reverse conversion information in the converted scan image of the image file.

19. The method according to claim 1, wherein the image file is displayable in a device having a color realization range in the first color gamut, and in a device having a color realization range in the second color gamut.

20. The apparatus according to claim 9, wherein the image file can be displayed in a device having a color realization range the first color gamut, and in a device having a color realization range in the second color gamut.

21. The method according to claim 1, further comprising displaying a restored version of the original scan image, on a display apparatus having a third color gamut, which is larger than either of the first and second color gamuts.
